(19) United States
(12) Patent Application Publication
(10) Pub. No.: US 2020/0050099 A1
(43) Pub. Date: Feb. 13, 2020

(54) ASSIST FEATURE PLACEMENT BASED ON MACHINE LEARNING

(71) Applicant: ASML NETHERLANDS B.V., Veldhoven (NL)

(72) Inventors: Jing SU, Fremont, CA (US); Yi ZOU, Foster City, CA (US); Chenxi LIN, Newark, CA (US); Yu CAO, Saratoga, CA (US); Yen-Wen LU, Saratoga, CA (US); Been-Der CHEN, Milpitas, CA (US); Quan ZHANG, San Jose, CA (US); Stanislas Hugo Louis BARON, San Jose, CA (US); Ya LUO, Saratoga, CA (US)

(73) Assignee: ASML NETHERLANDS B.V., Veldhoven (NL)

(21) Appl. No.: 16/606,791

(22) PCT Filed: May 4, 2018
(86) PCT No.: PCT/EP2018/061488

§ 371 Date: Oct. 21, 2019

Related U.S. Application Data
(60) Provisional application No. 62/511,937, filed on May 26, 2017.

(51) Int. Cl. G03F 1/36; G06F 17/50; G06N 20/10; G05B 19/4097; G06K 9/46; G06T 7/60; G06T 7/00

(52) U.S. Cl. CPC G03F 1/36; G06F 17/5072; G06N 20/10; G06T 2207/30148; G06K 9/4604; G06T 7/60; G06T 7/0004; G05B 19/4097

(57) ABSTRACT

A method including: obtaining a portion of a design layout; determining characteristics of assist features based on the portion or characteristics of the portion; and training a machine learning model using training data including a sample whose feature vector includes the characteristics of the portion and whose label includes the characteristics of the assist features. The machine learning model may be used to determine characteristics of assist features of any portion of a design layout, even if that portion is not part of the training data.

### CROSS-REFERENCE TO RELATED APPLICATIONS

This application claims priority of U.S. application 62/511,937 which was filed on May 26, 2017 and which is incorporated herein in its entirety by reference.

### TECHNICAL FIELD

The description herein relates to lithographic apparatuses and processes, and more particularly to a tool and a method to place assist features into a design layout.

### BACKGROUND

A lithographic apparatus can be used, for example, in the manufacture of integrated circuits (ICs) or other devices. In such a case, a patterning device (e.g., a mask) may contain or provide a pattern corresponding to an individual layer of the device (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic apparatus, one target portion at a time. In one type of lithographic apparatus, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic apparatus will have a magnification factor M (generally <1), the speed F at which the substrate is moved will be a factor M times that at which the projection beam scans the patterning device.

Prior to the device fabrication procedure of transferring the pattern from the patterning device to the substrate of the device manufacturing process, the substrate may undergo various device fabrication procedures of the device manufacturing process, such as priming, resist coating and a soft bake. After exposure, the substrate may be subjected to other device fabrication procedures of the device manufacturing process, such as a post-exposure bake (PEB), development, and a hard bake. This array of device fabrication procedures is used as a basis to make an individual layer of a device, e.g., an IC. The substrate may then undergo various device fabrication procedures of the device manufacturing process such as etching, ion-implantation (doping), metallization, oxidation, chemo-mechanical polishing, etc., all intended to finish off the individual layer of the device. If several layers are required in the device, then the whole process, or a variant thereof, is repeated for each layer. Eventually, a device will be present in each target portion on the substrate. If there is a plurality of devices, these devices are then separated from one another by a technique such as dicing or sawing, whence the individual devices can be mounted on a carrier, connected to pins, etc.

So, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices.

This device manufacturing process may be considered a patterning process. A patterning process involves a patterning step, such as optical or nanoimprint lithography using a lithographic apparatus, to provide a pattern on a substrate and typically, but optionally, involves one or more related pattern processing steps, such as resist development by a development apparatus, baking of the substrate using a bake tool, etching using the pattern using an etch apparatus, etc. Further, one or more metrology processes are typically involved in the patterning process.

### SUMMARY

Disclosed herein is a method comprising: obtaining a portion of a design layout; determining characteristics of assist features based on the portion or characteristics of the portion; training, using a computer, a machine learning model using training data comprising a sample whose feature vector comprises the characteristics of the portion and whose label comprises the characteristics of the assist features.

According to an embodiment, the design layout is a binary design layout or a continuous tone design layout.

According to an embodiment, the characteristics of the portion comprise geometrical characteristics of patterns in the portion, statistical characteristics of the patterns in the portion, parameterization of the portion, or an image derived from the portion.

According to an embodiment, the parameterization of the portion is a projection of the portion on one or more basis functions.

According to an embodiment, the image is a pixelated image, a binary image or a continuous tone image.

According to an embodiment, the characteristics of the assist features comprise geometrical characteristics of the assist features, statistical characteristics of the assist features, or parameterization of the assist features.

According to an embodiment, the image is a pixelated image of the portion wherein the pixelated image is with respect to a reference aligned with a feature of the portion

Disclosed herein is a method comprising: obtaining a portion of a design layout or characteristics of the portion; using a computer, obtaining characteristics of assist features for the portion, using a machine learning model, based on the portion or the characteristics of the portion.

According to an embodiment, the characteristics of the portion comprises geometrical characteristics of patterns in the portion, statistical characteristics of patterns in the portion, parameterization of patterns in the portion, or an image derived from the portion.

According to an embodiment, the parameterization of the portion is a projection of the portion on one or more basis functions.

According to an embodiment, the image is a pixelated image, a binary image or a continuous tone image.

According to an embodiment, the image is an image pixelated using an edge of a pattern in the portion as a reference.

According to an embodiment, the characteristics of the assist features comprise geometrical characteristics of the assist features, statistical characteristics of the assist features, or parameterization of the assist features.

According to an embodiment, the method further comprises patterning a substrate using the portion of the design layout and the assist features, in a lithographic process.

According to an embodiment, the method further comprises using the characteristics of assist features as an initial condition for an optimizer or a resolution enhancement technique.

According to an embodiment, the method further comprises computing a confidence metric that indicates trustworthiness of the characteristics of the assist features.

According to an embodiment, the characteristics comprise a binary image of the assist features and the confidence metric indicates a probability for either tones of the binary image.

According to an embodiment, the machine learning model is probabilistic and the confidence metric comprises a probability distribution over a set of classes.

According to an embodiment, the confidence metric represents a similarity between the portion of the design layout and training data used to train the machine learning model.

According to an embodiment, when the confidence metric fails to satisfy a condition, the method further comprises retraining the machine learning model using training data comprising the characteristics of the portion.

According to an embodiment, when the confidence metric fails to satisfy a condition, the method further comprises determining the assist features by a method not using the machine learning model.

According to an embodiment, the confidence metric is computed based on an output of the machine learning model.

Disclosed herein is a computer program product comprising a computer readable medium having instructions recorded thereon, the instructions when executed by a computer implementing a method herein.

### BRIEF DESCRIPTION OF FIGURES

FIG. 1 is a block diagram of various subsystems of a lithography system.

FIG. 2 schematically depicts an embodiment of a lithographic cell or cluster.

FIG. 3 schematically depicts a method of placing assist features (assist features connected to main features or independent assist features) into a design layout.

FIG. 4A and FIG. 4B schematically show flows for a method of placing assist features using a machine learning model, according to an embodiment.

FIG. 4C schematically shows more details of pixelation using an edge of the design layout as reference.

FIG. 4D schematically shows that a pixelated image of a feature may be determined using a reference aligned to each of the edges of the feature.

FIG. 5 is a block diagram of an example computer system.

FIG. 6 is a schematic diagram of a lithographic projection apparatus.

FIG. 7 is a schematic diagram of another lithographic projection apparatus.

FIG. 8 is a more detailed view of the apparatus in FIG. 7.

### DETAILED DESCRIPTION

As semiconductor or other device manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic apparatuses that project a design layout onto a substrate using illumination from a deep-ultraviolet (e.g., 193 nm) illumination source or an extreme-ultraviolet (e.g., 13.52 nm) illumination source, creating individual functional elements having dimensions well below 30 nm.

This process in which features with dimensions smaller than the classical resolution limit of a lithographic apparatus are printed, is commonly known as low-k1 lithography, according to the resolution formula CD=k1λ/NA, where λ is the wavelength of radiation employed (currently in most cases 248 nm or 193 nm), NA is the numerical aperture of projection optics in the lithographic apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic apparatus or the design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

As an example of RET, OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, the term “mask,” “patterning device” and “design layout” can be used interchangeably, as in the context of RET, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another or non-geometrical optical effects such as diffraction and interference. Similarly, proximity effects may arise from diffusion and other chemical effects during post-exposure bake (PEB), resist development, and etching that generally follow lithography.

In order to increase the chance that the projected image of the design layout is in accordance with requirements of a given target circuit design, proximity effects may be predicted and compensated for, using sophisticated numerical models, corrections or pre-distortions of the design layout. The article “Full-Chip Lithography Simulation and Design Analysis—How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

One of the simplest forms of OPC is selective bias. Given a CD vs. pitch curve, all of the different pitches could be forced to produce the same CD, at least at best focus and exposure, by changing the CD at the patterning device level. Thus, if a feature prints too small at the substrate level, the patterning device level feature would be biased to be slightly larger than nominal, and vice versa. Since the pattern transfer process from patterning device level to substrate level is non-linear, the amount of bias is not simply the measured CD error at best focus and exposure times the reduction ratio, but with modeling and experimentation an appropriate bias can be determined. Selective bias is an incomplete solution to the problem of proximity effects, particularly if it is only applied at the nominal process condition. Even though such bias could, in principle, be applied to give uniform CD vs. pitch curves at best focus and exposure, once the exposure process varies from the nominal condition, each biased pitch curve will respond differently, resulting in different process windows for the different features. Therefore, the “best” bias to give identical CD vs. pitch may even have a negative impact on the overall process window, reducing rather than enlarging the focus and exposure range within which all of the target features print on the substrate within the desired process tolerance.

Other more complex OPC techniques have been developed for application beyond the one-dimensional bias example above. A two-dimensional proximity effect is line end shortening. Line ends have a tendency to “pull back” from their desired end point location as a function of exposure and focus. In many cases, the degree of end shortening of a long line end can be several times larger than the corresponding line narrowing. This type of line end pull back can result in catastrophic failure of the devices being manufactured if the line end fails to completely cross over the underlying layer it was intended to cover, such as a polysilicon gate layer over a source-drain region. Since this type of pattern is highly sensitive to focus and exposure, simply biasing the line end to be longer than the design length is inadequate because the line at best focus and exposure, or in an underexposed condition, would be excessively long, resulting either in short circuits as the extended line end touches neighboring structures, or unnecessarily large circuit sizes if more space is added between individual features in the circuit. Since one of the goals of integrated circuit design and manufacturing is to maximize the number of functional elements while minimizing the area required per chip, adding excess spacing is an undesirable solution.

Two-dimensional OPC approaches may help solve the line end pull back problem. Extra structures (also known as “assist features”) such as “hammerheads” or “serifs” may be added to line ends to effectively anchor them in place and provide reduced pull back over the entire process window. Even at best focus and exposure these extra structures are not resolved but they alter the appearance of the main feature without being fully resolved on their own. A “main feature” as used herein means a feature intended to print on a substrate under some or all conditions in the process window. Assist features can take on much more aggressive forms than simple hammerheads added to line ends, to the extent the pattern on the patterning device is no longer simply the desired substrate pattern upsized by the reduction ratio. Assist features such as serifs can be applied for many more situations than simply reducing line end pull back. Inner or outer serifs can be applied to any edge, especially two dimensional edges, to reduce corner rounding or edge extrusions. With enough selective biasing and assist features of all sizes and polarities, the features on the patterning device bear less and less of a resemblance to the final pattern desired at the substrate level. In general, the patterning device pattern becomes a pre-distorted version of the substrate-level pattern, where the distortion is intended to counteract or reverse the pattern deformation that will occur during the manufacturing process to produce a pattern on the substrate that is as close to the one intended by the designer as possible.

Another OPC technique involves using completely independent and non-resolvable assist features, instead of or in addition to those assist features (e.g., serifs) connected to the main features. The term “independent” here means that edges of these assist features are not connected to edges of the main features. These independent assist features are not intended or desired to print as features on the substrate, but rather are intended to modify the aerial image of a nearby main feature to enhance the printability and process tolerance of that main feature. These assist features (often referred to as “scattering bars” or “SBAR”) can include sub-resolution assist features (SRAF) which are features outside edges of the main features and sub-resolution inverse features (SRIF) which are features scooped out from inside the edges of the main features. The presence of a SBAR adds yet another layer of complexity to a patterning device pattern. A simple example of a use of scattering bars is where a regular array of non-resolvable scattering bars is drawn on both sides of an isolated line feature, which has the effect of making the isolated line appear, from an aerial image standpoint, to be more representative of a single line within an array of dense lines, resulting in a process window much closer in focus and exposure tolerance to that of a dense pattern. The common process window between such a decorated isolated feature and a dense pattern will have a larger common tolerance to focus and exposure variations than that of a feature drawn as isolated at the patterning device level.

An assist feature may be viewed as a difference between features on a patterning device and features in the design layout. The terms “main feature” and “assist feature” do not imply that a particular feature on a patterning device must be labeled as one or the other.

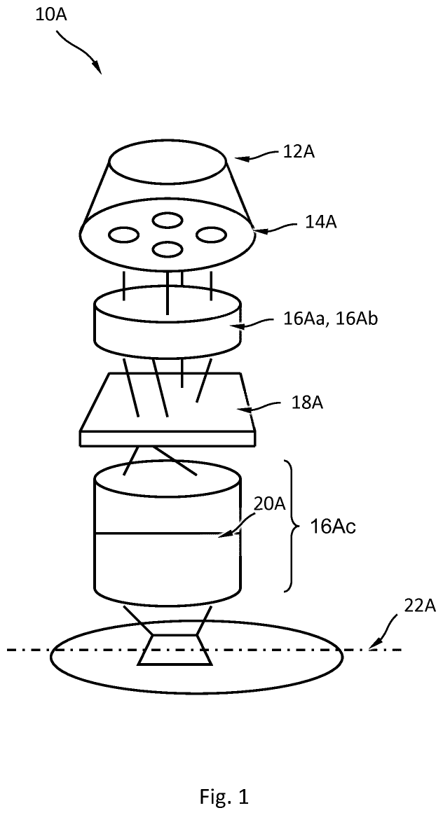

As a brief introduction, FIG. 1 illustrates an exemplary lithographic projection apparatus 10A. Major components include illumination optics which define the partial coherence (denoted as sigma) and which may include optics 14A, 16Aa and 16Ab that shape radiation from a radiation source 12A, which may be a deep-ultraviolet excimer laser source or other type of source including an extreme ultra violet (EUV) source (as discussed herein, the lithographic projection apparatus itself need not have the radiation source); and optics 16Ac that project an image of a patterning device pattern of a patterning device 18A onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=sin(Θₘₐₓ).

In a lithographic projection apparatus, projection optics direct and shape the illumination from a source via a patterning device and onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics.

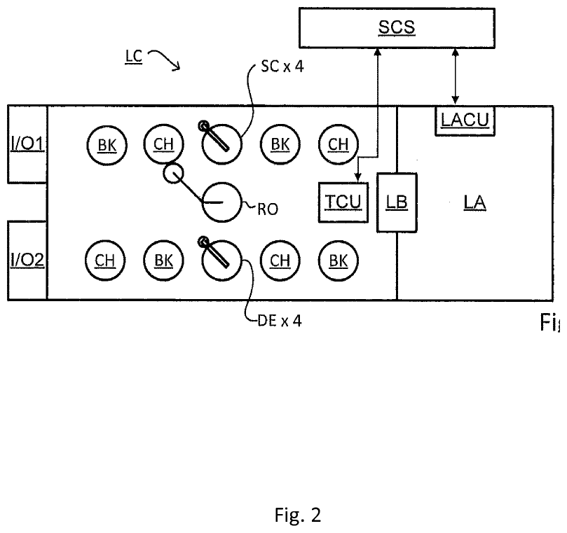

As shown in FIG. 2, the lithographic apparatus LA may form part of a lithographic cell LC, also sometimes referred to as a lithocell or lithocluster, which also includes apparatus to perform one or more pre- and post-exposure processes on a substrate. Conventionally these include one or more spin coaters SC to deposit a resist layer, one or more developers DE to develop exposed resist, one or more chill plates CH and one or more bake plates BK. A substrate handler, or robot, RO picks up a substrate from input/output ports I/O1, I/O2, moves it between the different process devices and delivers it to the loading bay LB of the lithographic apparatus. These devices, which are often collectively referred to as the track, are under the control of a track control unit TCU which is itself controlled by the supervisory control system SCS, which also controls the lithographic apparatus via lithographic control unit LACU. Thus, the different apparatus may be operated to maximize throughput and processing efficiency. The lithographic cell LC may further comprises one or more etchers to etch the substrate and one or more measuring devices configured to measure a parameter of the substrate. The measuring device may comprise an optical measurement device configured to measure a physical parameter of the substrate, such as a scatterometer, a scanning electron microscope, etc. The measuring device may be incorporated in the lithographic apparatus LA. An embodiment of the invention may be implemented in or with the supervisory control system SCS or the lithographic control unit LACU. For example, data from the supervisory control system SCS or the lithographic control unit LACU may be used by an embodiment of the invention and one or more signals from an embodiment of the invention may be provided to the supervisory control system SCS or the lithographic control unit LACU.

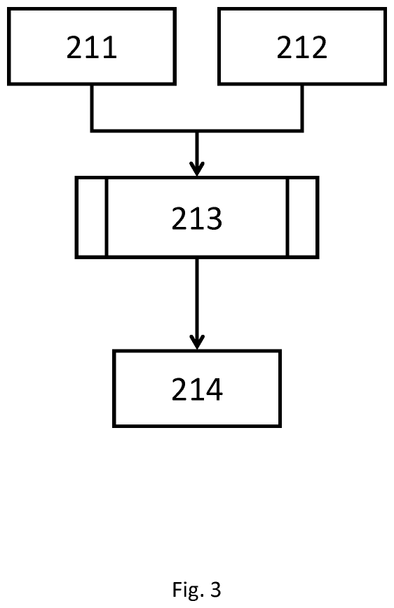

FIG. 3 schematically depicts a method of placing assist features (assist features connected to main features or independent assist features) into a design layout. The design layout may be a design layout before application of a RET or a design layout after application of a RET. The design layout may be binary or continuous tone. A computational or an empirical model 213 can be used to place (e.g., determining one or more characteristics, such as the existence, location, type, shape, etc., of) assist features. The model 213 can take into account one or more characteristics 211 (also referred to as a processing parameter) of the device manufacturing process, or one or more design layout parameters 212, or both. The one or more processing parameters 211 are one or more parameters associated with the device manufacturing process but not with the design layout. For example, the one or more processing parameters 211 may include a characteristic of the illumination (e.g., intensity, pupil profile, etc.), a characteristic of the projection optics, dose, focus, a characteristic of the resist, a characteristic of development of the resist, a characteristic of post-exposure baking of the resist, or a characteristic of etching. The one or more design layout parameters 212 may include one or more shapes, sizes, relative locations, or absolute locations of various features on a design layout, and also overlapping of features on different design layouts. In an empirical model, the image (e.g., resist image, optical image, etch image) is not simulated; instead, the empirical model places an assist feature based on a correlation between the input (e.g., the one or more processing parameters 211 or the design layout parameters 212) and the assist features. In a computational model, a portion or a characteristic of the image is calculated, and the assist feature is placed based on the portion or the characteristic.

An example of an empirical model is a machine learning model. Both unsupervised machine learning and supervised machine learning models may be used to place assist features. Without limiting the scope of the invention, applications of supervised machine learning algorithms are described below.

Supervised learning is the machine learning task of inferring a function from labeled training data. The training data includes a set of training examples. In supervised learning, each example is a pair having an input object (typically a vector) and a desired output value (also called the supervisory signal). A supervised learning algorithm analyzes the training data and produces an inferred function, which can be used for mapping new examples. An optimal scenario will allow the algorithm to correctly determine the class labels for unseen instances. This requires the learning algorithm to generalize from the training data to unseen situations in a “reasonable” way.

Given a set of N training examples of the form {(x₁,y₁), (x₂,y₂), . . . , (x_{N},y_{N})} such that xᵢ is the feature vector of the i-th example and yᵢ is its label (i.e., class), a learning algorithm seeks a function g: X→Y, where X is the input space and Y is the output space. A feature vector is an n-dimensional vector of numerical features that represent some object. Many algorithms in machine learning require a numerical representation of objects, since such representations facilitate processing and statistical analysis. When representing images, the feature values might correspond to the pixels of an image, when representing texts perhaps term occurrence frequencies. The vector space associated with these vectors is often called the feature space. The function g is an element of some space of possible functions G, usually called the hypothesis space. It is sometimes convenient to represent g using a scoring function f: X×Y→ [symbol] such that g is defined as returning the y value that gives the highest score:

$$g ( x ) = arg {max}_{y} f ( x , y ) .$$

denote the space of scoring functions.

Although G and F can be any space of functions, many learning algorithms are probabilistic models where g takes the form of a conditional probability model g(x)=P(y|x), or f takes the form of a joint probability model f(x,y)=P(x,y). For example, naive Bayes and linear discriminant analysis are joint probability models, whereas logistic regression is a conditional probability model.

There are two basic approaches to choosing f or g: empirical risk minimization and structural risk minimization. Empirical risk minimization seeks the function that best fits the training data. Structural risk minimization includes a penalty function that controls the bias/variance tradeoff.

In both cases, it is assumed that the training set has a sample of independent and identically distributed pairs (xᵢ,yᵢ). In order to measure how well a function fits the training data, a loss function L: Y×Y→ [symbol] ^{≥0} is defined. For training example (xᵢ,yᵢ), the loss of predicting the value ŷ is L(yᵢ,ŷ).

The risk R(g) of function g is defined as the expected loss of g. This can be estimated from the training data as

$${R}_{emp} ( g ) = \frac{1}{N} {\sum }_{i} L ( {y}_{i} , g ( {x}_{i} ) ) .$$

Exemplary models of supervised learning include decision trees, ensembles (bagging, boosting, random forest), k-NN, linear regression, naive Bayes, neural networks, logistic regression, perceptron, support vector machine (SVM), relevance vector machine (RVM), and deep learning.

SVM is an example of supervised learning model, which analyzes data and recognizes patterns and can be used for classification and regression analysis. Given a set of training examples, each marked as belonging to one of two categories, a SVM training algorithm builds a model that assigns new examples into one category or the other, making it a non-probabilistic binary linear classifier. A SVM model is a representation of the examples as points in space, mapped so that the examples of the separate categories are divided by a clear gap that is as wide as possible. New examples are then mapped into that same space and predicted to belong to a category based on which side of the gap they fall on.

In addition to performing linear classification, SVMs can efficiently perform a non-linear classification using what is called the kernel methods, implicitly mapping their inputs into high-dimensional feature spaces.

Kernel methods involve a user-specified kernel, i.e., a similarity function over pairs of data points in raw representation. Kernel methods owe their name to the use of kernel functions, which enable them to operate in a high-dimensional, implicit feature space without ever computing the coordinates of the data in that space, but rather by simply computing the inner products between the images of all pairs of data in the feature space. This operation is often computationally cheaper than the explicit computation of the coordinates. This approach is called the “kernel trick.”

The effectiveness of SVM depends on the selection of kernel, the kernel's parameters, and soft margin parameter C. A common choice is a Gaussian kernel, which has a single parameter γ. The best combination of C and γ is often selected by a grid search (also known as “parameter sweep”) with exponentially growing sequences of C and γ, for example, C∈{2⁻⁵, 2⁻⁴, . . . , 2¹⁵, 2¹⁶}; γ∈{2¹⁵, 2⁻¹⁴, . . . , 2⁴, 2⁵}.

A grid search is an exhaustive searching through a manually specified subset of the hyperparameter space of a learning algorithm. A grid search algorithm is guided by some performance metric, typically measured by cross-validation on the training set or evaluation on a held-out validation set.

Each combination of parameter choices may be checked using cross validation, and the parameters with best cross-validation accuracy are picked.

Cross-validation, sometimes called rotation estimation, is a model validation technique for assessing how the results of a statistical analysis will generalize to an independent data set. It is mainly used in settings where the goal is prediction, and one wants to estimate how accurately a predictive model will perform in practice. In a prediction problem, a model is usually given a dataset of known data on which training is run (training dataset), and a dataset of unknown data (or first seen data) against which the model is tested (testing dataset). The goal of cross validation is to define a dataset to “test” the model in the training phase (i.e., the validation dataset), in order to limit problems like overfitting, give an insight on how the model will generalize to an independent data set (i.e., an unknown dataset, for instance from a real problem), etc. One round of cross-validation involves partitioning a sample of data into complementary subsets, performing the analysis on one subset (called the training set), and validating the analysis on the other subset (called the validation set or testing set). To reduce variability, multiple rounds of cross-validation are performed using different partitions, and the validation results are averaged over the rounds.

The final model, which can be used for testing and for classifying new data, is then trained on the entire training set using the selected parameters.

Another example of supervised learning is regression. Regression infers the relationships between a dependent variable and one or more independent variables, from a set of values of the dependent variables and corresponding values of the independent variables. Regression may estimate the conditional expectation of the dependent variable given the independent variables. The inferred relationships may be called the regression function. The inferred relationships may be probabilistic.

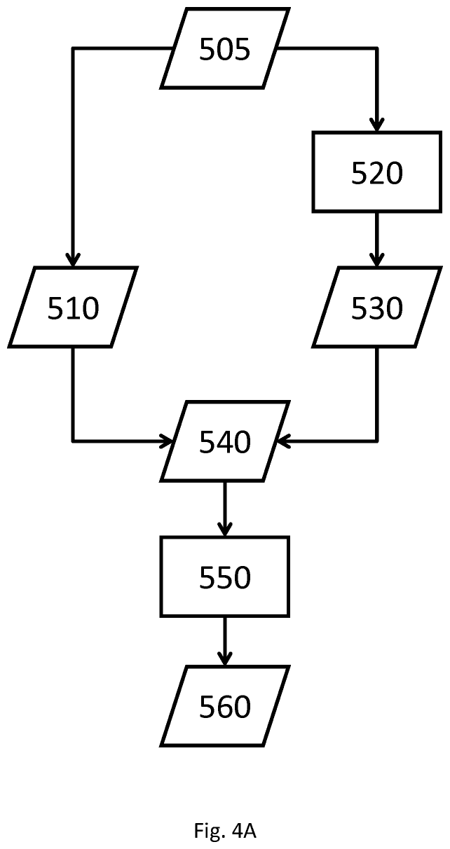

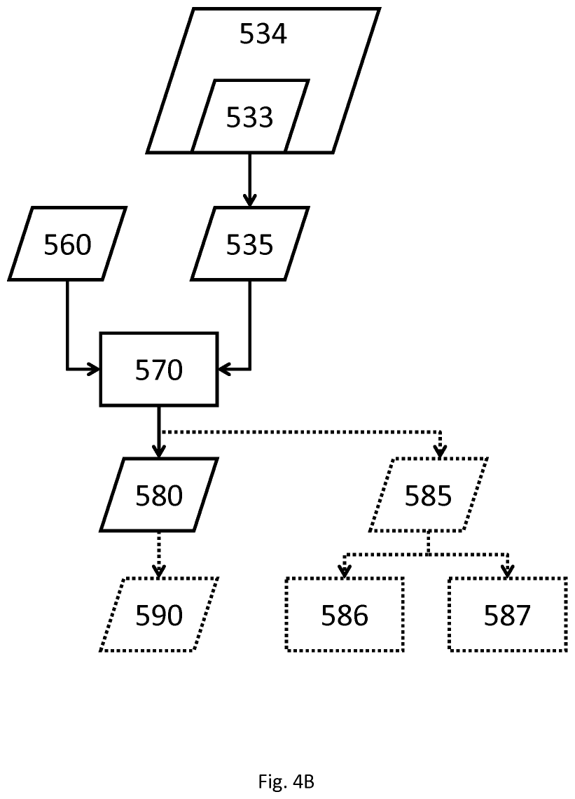

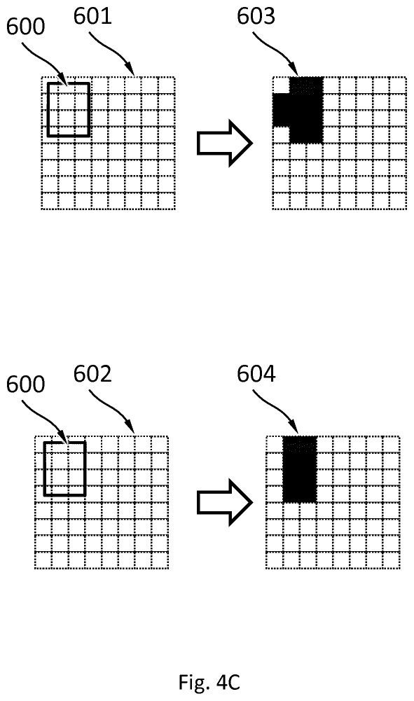

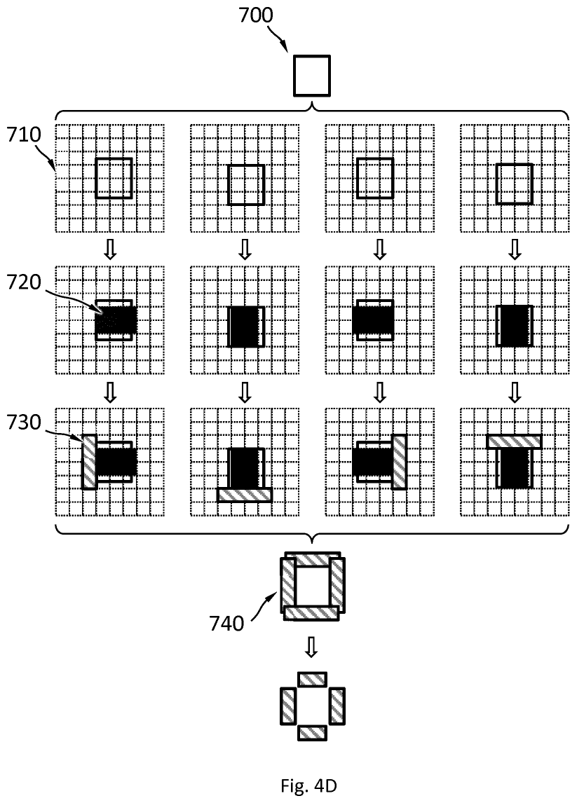

FIG. 4A and FIG. 4B schematically show flows for a method of placing assist features using a machine learning model, according to an embodiment. FIG. 4A schematically shows a flow for training the machine learning model. One or more values of one or more characteristics 510 of a portion 505 of a design layout are obtained. The design layout may be a binary design layout, a continuous tone design layout (e.g., rendered from a binary design layout), or a design layout of another suitable form. The one or more characteristics 510 may include a geometrical characteristic (e.g., an absolute location, a relative location, or shape) of one or more patterns in the portion 505. The one or more characteristics 510 may include one or more statistical characteristics of the one or more patterns in the portion 505. Examples of a statistical characteristic of a pattern in the portion 505 may include an average or variance of a geometric dimension of one or more patterns. The one or more characteristics 510 may include parameterization of the portion 505 (i.e., one or more values of a function of the portion 505), such as projection on certain basis functions. The one or more characteristics 510 may include an image (pixelated, binary Manhattan, binary curvilinear, or continuous tone) derived from the portion 505.

In procedure 520, one or more characteristics 530 of assist features are determined using any suitable method, based on the portion 505 or one or more characteristics 510 thereof. For example, the one or more characteristics 530 of assist features may be determined using a method described in U.S. Pat. No. 9,111,062, or described Y. Shen, et al., Level-Set-Based Inverse Lithography For Photomask Synthesis, Optics Express, Vol. 17, pp. 23690-23701 (2009), the disclosures of which are hereby incorporated by reference in their entirety. For example, the one or more characteristics 530 may include one or more geometrical characteristics (e.g., absolute location, relative location, or shape) of the assist features, one or more statistical characteristics of the assist features, or parameterization of the assist features. Examples of a statistical characteristic of the assist features may include an average or variance of a geometric dimension of the assist features.

Values of the one or more characteristics 510 of the portion of the design layout and the one or more characteristics 530 of the assist features are included in training data 540 as a sample. The one or more characteristics 510 are the feature vector (also called the input vector) of the sample and the one or more characteristics 530 are the label (also called the supervisory signal or answer vector) of the sample. In procedure 550, a machine learning model 560 is trained using the training data 540.

FIG. 4B schematically shows a flow for using the machine learning model 560 to place one or more assist features. A portion 533 of a design layout 534 or one or more characteristics 535 of the portion are obtained. Neither the portion 533 nor any other portion of the design layout 534 has to be part of the training data. The portion 533 may be a portion in a vicinity of an edge of the design layout 534. The one or more characteristics 535 may include one or more geometrical characteristics (e.g., absolute location, relative location, or shape) of one or more patterns in the portion 533. The one or more characteristics 535 may include one or more statistical characteristics of the one or more patterns in the portion 533. The one or more characteristics 535 may include parameterization of the portion 533, such as projection on certain basis functions. The one or more characteristics 535 may include an image (pixelated, binary Manhattan, binary curvilinear, or continuous tone) derived from the portion 533. For example, if the portion 533 is a portion in a vicinity of an edge of the design layout 534, the one or more characteristics 535 may be relative to the edge as a reference (e.g., a pixelated, binary Manhattan, binary curvilinear, or gray-scale image or a projection onto a basis, obtained using the edge as a reference), thereby the one or more characteristics 535 do not change even if the edge is moved relative to a reference fixed in the design layout, as further explained below in reference to FIG. 4C and FIG. 4D.

In procedure 570, the portion 534 or the one or more characteristics 535 are provided as input into the machine learning model 560 and one or more characteristics 580 of one or more assist features for the portion 533 are obtained as output from the machine learning model 560. The one or more characteristics 580 may include the one or more geometrical characteristics (e.g., absolute location, relative location, or shape) of the assist features. The one or more characteristics 580 may include parameterization of the assist features, such as projection on certain basis functions. The one or more characteristics 580 may include an image (pixelated, binary Manhattan, binary curvilinear, or continuous tone) of the assist features. The one or more characteristics 580 of the assist features may be adjusted to avoid conflicts among them, for example, using a method described in U.S. Patent Application Publication No. 2008/0301620, the disclosure of which is incorporated by reference in its entirety.

In optional procedure 590, a substrate is patterned using the portion 533 of the design layout 534 and the assist features, in a lithographic process.

In procedure 570, the machine learning model 560 may optionally compute a confidence metric 585, which indicates the trustworthiness of the one or more characteristics 580. For example, when the one or more characteristics 580 include a binary image (e.g., binary Manhattan image, binary curvilinear image) of the assist features, the confidence metric may be the probability for either tones of the binary image. Some machine learning models, such as naive Bayes, logistic regression and multilayer perceptron (when trained under an appropriate loss function) are naturally probabilistic. A probabilistic model outputs a probability distribution over a set of classes, rather than only outputting the most likely class that the input should belong to. Some other machine learning models such as support vector machines are not naturally probabilistic, but methods exist to turn them into probabilistic classifiers. A regression problem may be converted to a multi-class classification problem and then use probability as a metric, or use a bootstrap method to build many models and then calculate the variance of the model predictions. The confidence metric (e.g., entropy, GINI index, etc.) may be computed based on an output (e.g., a probability distribution over a set of classes) of the machine learning model.

Other forms of the confidence metric 585 may be possible. For example, for those portions of a design layout that are very different from the portions in the training data, the machine learning model has a relative high chance to be problematic. The confidence metric 585 that measures the similarity between the portion of the input and the portions in the training data may be constructed in a suitable way. A maximum Euclidean distance between the portion in the input and each of the portions of the training data can be such an example. In another example, the portions of the training data may be clustered into several groups and the Euclidean distances of the image of the input to the centers of each group may be used as the confidence metric 585.

If the confidence metric 585 fails to satisfy a condition (e.g., for indicating that the one more characteristics 580 are not sufficiently trustworthy), the one or more characteristics 580 may be disregarded and an assist feature may be placed using a different method (e.g., a method described in U.S. Pat. No. 9,111,062) in optional procedure 586 or the machine learning model 560 may be retrained, in optional procedure 587 (e.g., using the flow in FIG. 4A), using training data including the one or more characteristics 535 in the input that lead to the confidence metric 585 that fails the condition.

The assist feature whose characteristic 580 is produced by the machine learning model 570, in combination with the portion 533 of the design layout 534 may be used as an initial condition for another RET, such as OPC, illumination and patterning device pattern optimization (sometimes referred to as SMO), patterning device optimization (MO), or as an initial condition of a rigorous optimizer to speed up convergence. This is the other use case.

FIG. 4C schematically shows more details of pixelation using an edge of the design layout as reference. The pixelated image of a feature 600 may depend on the selection of a reference. For example, as shown in FIG. 4C, the pixelated image of the feature 600 using a reference 601 is pixelated image 603 but the pixelated image of the same feature 600 using a reference 602, which is merely shifted relative to the reference 601, is pixelated image 604, which is different from the pixelated image 603. To avoid this dependency of pixelation on the selection of the reference, a reference aligned to an edge (e.g., the right edge here) of, e.g., the reference 602, or a corner of the feature 600 may be used for pixelation of the feature 600. The references for different features may be different.

FIG. 4D schematically shows that a pixelated image 720 of a feature 700 may be determined using a reference 710 aligned to each of the edges of the feature 700. Each of the pixelated images 720 may be used as the characteristic 535 in the flow of FIG. 4B to obtain the one or more characteristic 580 of the assist features (e.g., shapes 730 of the assist features). Namely, for each edge, a set of one or more characteristics 580 of the assist features (e.g., shapes 730 of the assist features) is obtained. The set of one or more characteristics 580 (e.g., shapes 730 of the assist features) may be aligned with one another using the feature 700 as a reference, and merged together as a merged set of one or more characteristics of the assist feature (e.g., merged shapes 740 of the assist features). Conflicts in the merged set of one or more characteristics of the assist features may be then resolved (e.g., overlap in the merged shapes 740 removed). Though the pixelated image 720 is used here as an example of the one or more characteristics 535 obtained relative to an edge, the one or more characteristics 535 relative to the edge may be one or more other suitable characteristics such as a binary, or gray-scale image or a projection onto a basis, obtained using the edge as a reference.

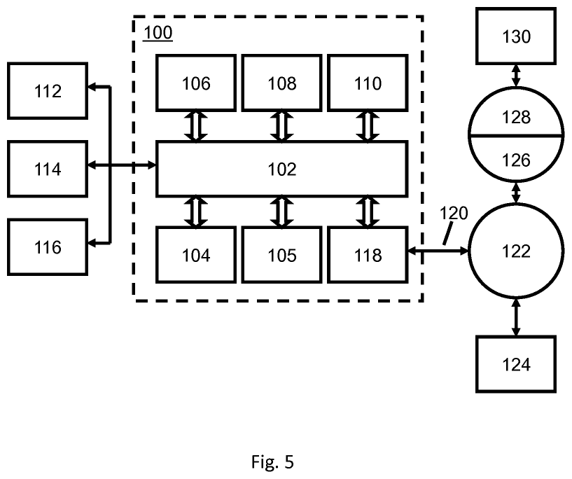

FIG. 5 is a block diagram that illustrates a computer system 100 which can assist in implementing methods and flows disclosed herein. Computer system 100 includes a bus 102 or other communication mechanism to communicate information, and a processor 104 (or multiple processors 104 and 105) coupled with bus 102 to process information. Computer system 100 may also include a main memory 106, such as a random access memory (RAM) or other dynamic storage device, coupled to bus 102 to store or supply information and instructions to be executed by processor 104. Main memory 106 may be used to store or supply temporary variables or other intermediate information during execution of instructions to be executed by processor 104. Computer system 100 may further include a read only memory (ROM) 108 or other static storage device coupled to bus 102 to store or supply static information and instructions for processor 104. A storage device 110, such as a magnetic disk or optical disk, may be provided and coupled to bus 102 to store or supply information and instructions.

Computer system 100 may be coupled via bus 102 to a display 112, such as a cathode ray tube (CRT) or flat panel or touch panel display, to display information to a computer user. An input device 114, including alphanumeric and other keys, may be coupled to bus 102 to communicate information and command selections to processor 104. Another type of user input device may be cursor control 116, such as a mouse, a trackball, or cursor direction keys, to communicate direction information and command selections to processor 104 and to control cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of a process described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a disk or memory of a remote computer. The remote computer can load the instructions into its dynamic memory and send the instructions over a communications path. Computer system 100 can receive the data from the path and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may include a communication interface 118 coupled to bus 102. Communication interface 118 provides a two-way data communication coupling to a network link 120 that is connected to a network 122. For example, communication interface 118 may provide a wired or wireless data communication connection. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through network 122 to a host computer 124 or to data equipment operated by an Internet Service Provider (ISP) 126. ISP 126 in turn provides data communication services through the worldwide packet data communication network, now commonly referred to as the “Internet” 128. Network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, network 122 and communication interface 118. One such downloaded application may provide for the code to implement a method herein, for example. The received code may be executed by processor 104 as it is received, or stored in storage device 110, or other non-volatile storage for later execution. In this manner, computer system 100 may obtain application code in the form of a carrier wave.

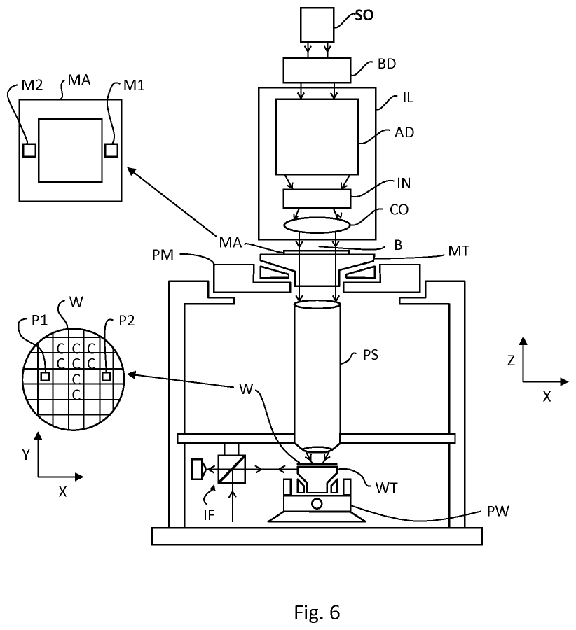

FIG. 6 schematically depicts an exemplary lithographic projection apparatus. The apparatus comprises:
an illumination system IL, to condition a beam B of radiation. In this particular case, the illumination system also comprises a radiation source SO;
a first object table (e.g., mask table) MT provided with a patterning device holder to hold a patterning device MA (e.g., a reticle), and connected to a first positioner PM to accurately position the patterning device with respect to item PS;
a second object table (substrate table) WT provided with a substrate holder to hold a substrate W (e.g., a resist-coated silicon wafer), and connected to a second positioner PW to accurately position the substrate with respect to item PS;
a projection system PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed a conditioner, such as a beam expander. The illuminator IL may comprise an adjuster AD configured to set the outer or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 6 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors BD); this latter scenario is often the case when the source SO is an excimer laser (e.g., based on KrF, ArF or F₂ lasing).

The beam B subsequently intercepts the patterning device MA, which is held on a patterning device table MT. Having traversed the patterning device MA, the beam B passes through the projection system PS, which focuses the beam B onto a target portion C of the substrate W. With the aid of the second positioner PW (and interferometer IF), the substrate table WT can be moved accurately, e.g. so as to position different target portions C in the path of the beam B. Similarly, the first positioner PM can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 6.

Patterning device (e.g., mask) MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the patterning device alignment marks may be located between the dies. Small alignment markers may also be included within dies, in amongst the device features, in which case it is desirable that the markers be as small as possible and not require any different imaging or process conditions than adjacent features.

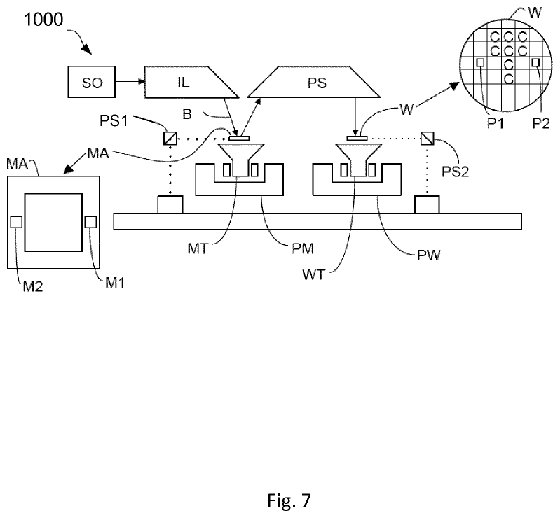

FIG. 7 schematically depicts another exemplary lithographic projection apparatus 1000. The lithographic projection apparatus 1000 includes:
a source collector module SO;
an illumination system (illuminator) IL configured to condition a radiation beam B (e.g. EUV radiation);
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective mask). It is to be noted that because most materials are absorptive within the EUV wavelength range, the patterning device may have a multilayer reflector comprising, for example, a multi-stack of molybdenum and silicon. In one example, the multi-stack reflector has a 40 layer pairs of molybdenum and silicon. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 7, the illuminator IL receives an extreme ultra violet (EUV) radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 7, to provide the laser beam to excite the fuel. The resulting plasma emits output radiation, e.g., EUV radiation, which is collected using a radiation collector, disposed in the source collector module. The laser and the source collector module may be separate entities, for example when a CO₂ laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors or a beam expander. In other cases the source may be an integral part of the source collector module, for example when the source is a discharge produced plasma EUV generator, often termed as a DPP source.

The illuminator IL may comprise an adjuster configured to adjust the angular intensity distribution of the radiation beam. Generally, at least the outer or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X or Y direction so that a different target portion C can be exposed.
2. In scan mode, the support structure (e.g. mask table) MT and the substrate table WT are scanned synchronously in a given direction (the so-called “scan direction”) while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Further, the lithographic apparatus may be of a type having two or more tables (e.g., two or more substrate table, two or more patterning device tables, or a substrate table and a table without a substrate). In such “multiple stage” devices the additional tables may be used in parallel, or preparatory steps may be carried out on one or more tables while one or more other tables are being used for exposures.

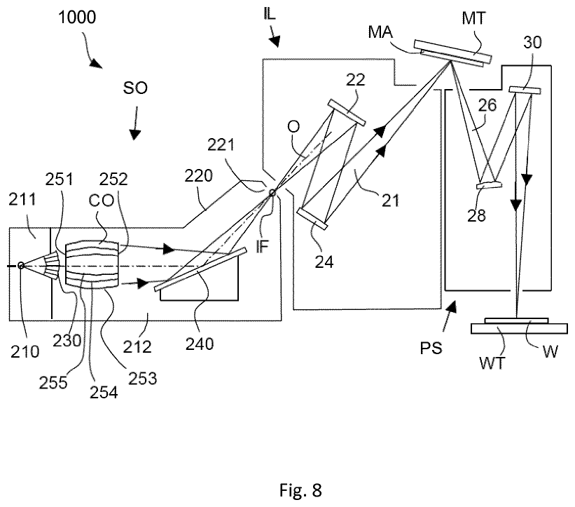

FIG. 8 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 8.

Collector optic CO, as illustrated in FIG. 8, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is desirably used in combination with a discharge produced plasma source, often called a DPP source. Alternatively, the source collector module SO may be part of an LPP radiation system.

The embodiments may further be described using the following clauses:

1. A method comprising:

obtaining a portion of a design layout;

determining a characteristic of assist features based on the portion or a characteristic of the portion; and

training, by a hardware computer, a machine learning model using training data comprising a sample whose feature vector comprises the characteristic of the portion and whose label comprises the characteristic of the assist features.

2. The method of clause 1, wherein the design layout is a binary design layout or a continuous tone design layout.
3. The method of any clause 1 or clause 2, wherein the characteristic of the portion comprise a geometrical characteristic of a pattern in the portion, a statistical characteristic of the pattern in the portion, parameterization of the portion, or an image derived from the portion.
4. The method of clause 3, wherein the characteristic of the portion comprises the parameterization of the portion and wherein the parameterization of the portion is a projection of the portion on one or more basis functions.
5. The method of clause 3, wherein the characteristic of the portion comprises the image and wherein the image is a pixelated image, a binary image or a continuous tone image.
6. The method of clause 3, wherein the characteristic of the portion comprises the image and wherein the image is a pixelated image of the portion and the pixelated image is with respect to a reference aligned with a feature of the portion.
7. The method of any of clauses 1-6, wherein the characteristic of the assist features comprise a geometrical characteristic of the assist features, a statistical characteristic of the assist features, or parameterization of the assist features.
8. A method comprising:

obtaining a portion of a design layout or a characteristic of the portion; and

obtaining, by a hardware computer, a characteristic of assist features for the portion, using a machine learning model, based on the portion or the characteristic of the portion.

9. The method of clause 8, wherein the characteristic of the portion comprises a geometrical characteristic of a pattern in the portion, a statistical characteristic of a pattern in the portion, a parameterization of a pattern in the portion, or an image derived from the portion.
10. The method of clause 9, wherein the characteristic of the portion comprises the parameterization of the portion and wherein the parameterization of the portion is a projection of the portion on one or more basis functions.
11. The method of clause 9, wherein the characteristic of the portion comprises the image and wherein the image is a pixelated image, a binary image or a continuous tone image.
12. The method of clause 9, wherein the characteristic of the portion comprises the image and the image is an image pixelated using an edge of a pattern in the portion as a reference.
13. The method of any of clauses 8-12, wherein the characteristic of the assist features comprise a geometrical characteristic of the assist features, a statistical characteristic of the assist feature, or a parameterization of the assist feature.
14. The method of any of clauses 8-13, further comprising patterning a substrate using the portion of the design layout and the assist feature, in a lithographic process.
15. The method of any of clauses 8-13, further comprising using the characteristic of the assist feature as an initial condition for an optimizer or a resolution enhancement technique.
16. The method of any of clauses 8-14, further comprising computing a confidence metric that indicates trustworthiness of the characteristic of the assist feature.
17. The method of clause 16, wherein the characteristic comprise a binary image of the assist feature and wherein the confidence metric indicates a probability for either tones of the binary image.
18. The method of clause 16, wherein the machine learning model is probabilistic and wherein the confidence metric comprises a probability distribution over a set of classes.
19. The method of clause 16, wherein the confidence metric represents a similarity between the portion of the design layout and training data used to train the machine learning model.
20. The method of clause 16, wherein responsive to the confidence metric failing to satisfy a condition, the method further comprises retraining the machine learning model using training data comprising the characteristic of the portion.
21. The method of clause 16, wherein responsive to the confidence metric failing to satisfy a condition, the method further comprises determining the assist feature by a method not using the machine learning model.
22. The method of clause 16, wherein the confidence metric is computed based on an output of the machine learning model.
23. A computer program product comprising a computer readable medium having instructions recorded thereon, the instructions when executed by a computer implementing the method of any of clauses 1-22.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum.

The concepts disclosed herein may be applicable to any device manufacturing process involving a lithographic apparatus, and may be especially useful with emerging imaging technologies capable of producing wavelengths of an increasingly smaller size. Emerging technologies already in use include deep ultraviolet (DUV) lithography that is capable of producing a 193 nm wavelength with the use of an ArF laser, and even a 157 nm wavelength with the use of a fluorine laser. Moreover, EUV lithography is capable of producing wavelengths within a range of 5-20 nm.

While the concepts disclosed herein may be used for device manufacturing on a substrate such as a silicon wafer, it shall be understood that the disclosed concepts may be used with any type of lithographic imaging systems, e.g., those used for imaging on substrates other than silicon wafers.

The patterning device referred to above comprises or can form a design layout. The design layout can be generated utilizing a CAD (computer-aided design) program. This process is often referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. The design rule limitations are typically referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

So, as noted, microlithography is a significant step in the manufacturing of devices such as ICs, where patterns formed on substrates define functional elements of the ICs, such as microprocessors, memory chips etc. Similar lithographic techniques are also used in the formation of flat panel displays, micro-electro mechanical systems (MEMS) and other devices.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

The term “optimizing” and “optimization” as used herein refers to or means adjusting a patterning process apparatus, one or more steps of a patterning process, etc. such that results and/or processes of patterning have more desirable characteristics, such as higher accuracy of transfer of a design layout on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, applicants have grouped these inventions into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such inventions or all aspects of such inventions.

It should be understood that the description and the drawings are not intended to limit the invention to the particular form disclosed, but to the contrary, the intention is to cover all modifications, equivalents, and alternatives falling within the spirit and scope of the present invention as defined by the appended claims.

Modifications and alternative embodiments of various aspects of the invention will be apparent to those skilled in the art in view of this description. Accordingly, this description and the drawings are to be construed as illustrative only and are for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description of the invention. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every.

The descriptions above are intended to be illustrative, not limiting. Thus, it will be apparent to one skilled in the art that modifications may be made as described without departing from the scope of the claims set out below.

1. A method comprising:
obtaining a portion of a design layout or a characteristic of the portion; and
obtaining, by a hardware computer system, a characteristic of an assist feature for the portion, using a machine learning model, based on the portion or the characteristic of the portion.

2. The method of claim 1, comprising obtaining the characteristic of the portion and obtaining the characteristic of an assist features based on the characteristic of the portion, wherein the characteristic of the portion comprises a geometrical characteristic of a pattern in the portion, a statistical characteristic of a pattern in the portion, a parameterization of a pattern in the portion, or an image derived from the portion.

3. The method of claim 2, wherein the characteristic of the portion comprises the parameterization of a pattern in the portion and wherein the parameterization is a projection of the portion on one or more basis functions.

4. The method of claim 2, wherein the characteristic of the portion comprises the image derived from the portion and wherein the image is a pixelated image, a binary image or a continuous tone image.

5. The method of claim 2, wherein the characteristic of the portion comprises the image derived from the portion and the image is an image pixelated using an edge of a pattern in the portion as a reference.

6. The method of claim 1, wherein the characteristic of the assist feature comprises a geometrical characteristic of the assist feature, a statistical characteristic of the assist feature, or a parameterization of the assist feature.

7. The method of claim 1, further comprising patterning a substrate using the portion of the design layout and the assist feature, in a lithographic process.

8. The method of claim 1, further comprising using the characteristic of the assist feature as an initial condition for an optimizer or a resolution enhancement technique.

9. The method of claim 1, further comprising computing a confidence metric that indicates trustworthiness of the characteristic of the assist feature.

10. The method of claim 9, wherein the characteristic of the assist features comprises a binary image of the assist feature and wherein the confidence metric indicates a probability for either tones of the binary image.

11. The method of claim 9, wherein the machine learning model is probabilistic and wherein the confidence metric comprises a probability distribution over a set of classes.

12. The method of claim 9, wherein the confidence metric represents a similarity between the portion of the design layout and training data used to train the machine learning model.

13. The method of claim 9, further comprising, responsive to the confidence metric failing to satisfy a condition, retraining the machine learning model using training data comprising the characteristic of the portion.

14. The method of claim 9, further comprising, responsive to the confidence metric failing to satisfy a condition, determining the assist feature by a method not using the machine learning model.

15. The method of claim 9, wherein the confidence metric is computed based on an output of the machine learning model.

16. A computer program product comprising a non-transitory computer readable medium having instructions therein, the instructions, upon execution by a computer system, configured to cause the computer system to at least:
obtain a portion of a design layout or a characteristic of the portion; and
determine a characteristic of assist features for the portion, using a machine learning model, based on the portion or the characteristic of the portion.

17. A method comprising:
obtaining a portion of a design layout;
determining a characteristic of assist features based on the portion or a characteristic of the portion; and
training, by a hardware computer system, a machine learning model using training data comprising a sample whose feature vector comprises the characteristic of the portion and whose label comprises the characteristic of assist features.

18. The method of claim 17, wherein the characteristic of the portion comprises a geometrical characteristic of a pattern in the portion, a statistical characteristic of the pattern in the portion, a parameterization of the portion, or an image derived from the portion.

19. The method of claim 17, wherein the characteristic of the assist features comprises a geometrical characteristic of assist features, a statistical characteristic of assist features, or a parameterization of assist features.

20. A computer program product comprising a non-transitory computer readable medium having instructions therein, the instructions, upon execution by a computer system, configured to cause the computer system to at least cause performance of the method of claim 17.
